(19) United States
(12) Patent Application Publication
(10) Pub. No.: US 2014/0060894 A1
(43) Pub. Date: Mar. 6, 2014

(54) CLIP ASSEMBLY AND HEAT DISSIPATION DEVICE INCORPORATING THE SAME

(71) Applicants: CHAMP TECH OPTICAL (FOSHAN) CORPORATION, Foshan (CN); FOXCONN TECHNOLOGY CO., LTD., New Taipei (TW)

(72) Inventors: MING-WEI CHEN, Foshan (CN); JING ZHANG, Foshan (CN); TAO LI, Foshan (CN)

(73) Assignees: FOXCONN TECHNOLOGY CO., LTD., New Taipei (TW); CHAMP TECH OPTICAL (FOSHAN) CORPORATION, Foshan (CN)

(21) Appl. No.: 13/726,544

(22) Filed: Dec. 25, 2012

(30) Foreign Application Priority Data
Aug. 31, 2012 (CN) 2012103177841

(51) Int. Cl. F16B 2/24; H05K 1/02

(52) U.S. Cl. CPC F16B 2/248; H05K 1/0203
USPC 174/252; 24/462

(57) ABSTRACT

An exemplary heat dissipation device includes a heat sink and a clip assembly spanning the heat sink. The clip assembly includes two wire clips and two fasteners engaging with the wire clips, respectively. The wire clip includes two opposite engaging arms, and an engaging section interconnecting the two engaging arms. Each engaging arm includes a connecting section extending outwardly from the engaging section, and a hook bent outwardly from a free end of the connecting section. The hooks of each wire clip are hooked in the heat sink, each fastener extends through the engaging section of the corresponding wire clip, the engaging section of the wire clip is resiliently pressed by the fastener, and the heat sink is pressed downwardly by the connecting section of the wire clip.

### BACKGROUND

1. Technical Field

The present disclosure relates to heat dissipation apparatuses, and more particular to a clip assembly and a heat dissipation device incorporating the clip assembly.

2. Description of Related Art

With advancements in computer technology, many electronic devices such as central processing units and chips operate at a high speed nowadays. It is well known that the more rapidly the electronic devices operate, the more heat they generate. If the heat is not timely dissipated, the stability of operation of the electronic device may be impacted severely. Generally, in order to ensure that the electronic device runs normally, a heat dissipation device is used to dissipate the heat generated by the electronic device.

Typically, the heat dissipation device includes a heat sink and a clip assembly. The clip assembly facilitates close attachment of the heat sink onto an electronic device, so that the heat sink can efficiently dissipate heat generated by the electronic device. The clip assembly usually has a wire clip, which is integrally made of a resilient metal wire. The clip abuts against the heat sink, with two ends of the clip locked on a printed circuit board on which the electronic device is mounted, thereby providing pressure for securing the heat sink on the electronic device. However, the amount of pressure directly exerted downwardly against the heat sink by the clip is difficult to control. When the fastening force is too small, the heat-dissipation efficiency is usually low because of loose attachment of the heat sink onto the electronic device. Conversely, when the fastening force is too large, it may damage the electronic device.

What is needed, therefore, is an improved clip assembly and a heat dissipation device incorporating the clip assembly which can overcome the above described shortcomings

### BRIEF DESCRIPTION OF THE DRAWINGS

FIG. 1 is an isometric, exploded view of a heat dissipation device according to an exemplary embodiment of the present disclosure.

FIG. 2 is an assembled view of the heat dissipation device of FIG. 1.

FIG. 3 is a schematic, side view of the heat dissipation device of FIG. 2 mounted on a printed circuit board.

### DETAILED DESCRIPTION

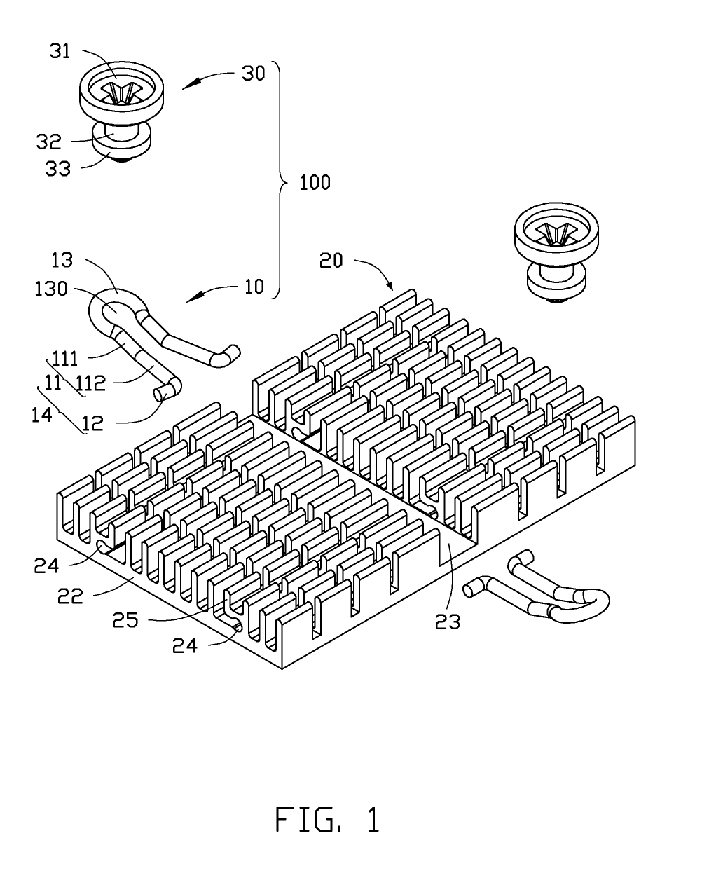

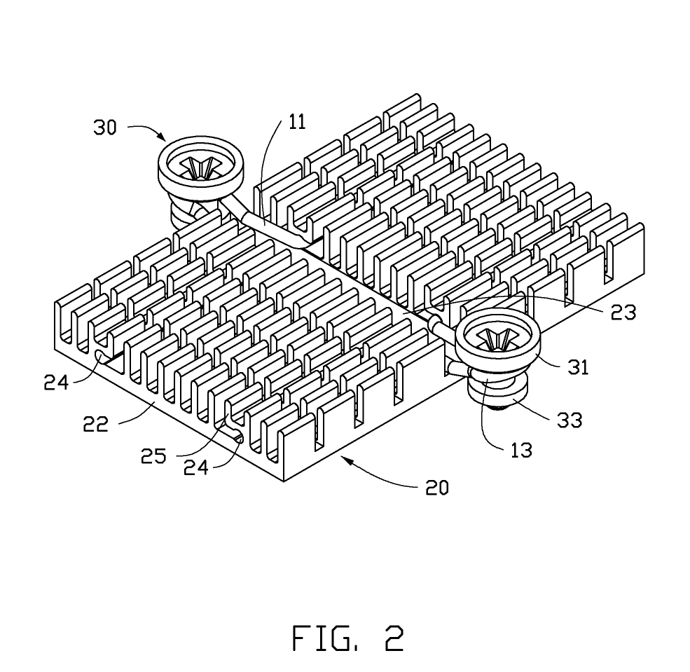

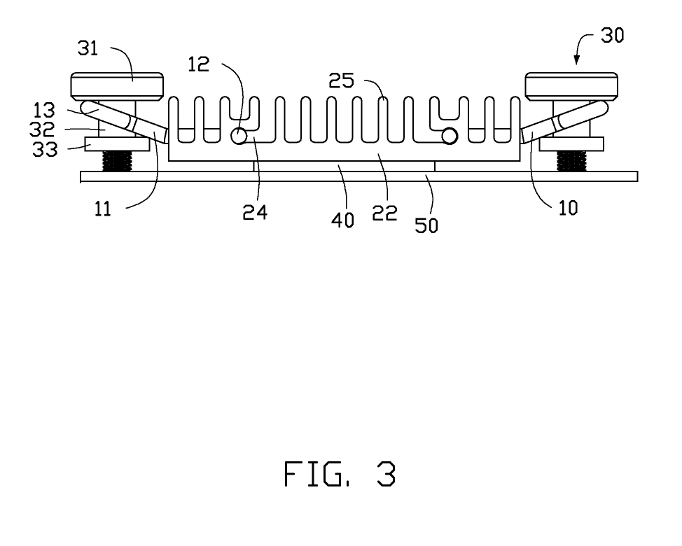

Referring to FIGS. 1 through 3, a heat dissipation device according to an exemplary embodiment is used to thermally contact an electronic component 40 which is mounted on a printed circuit board 50. The heat dissipation device comprises a heat sink 20, and a clip assembly 100 securing the heat sink 20 to the printed circuit board 50.

The clip assembly 100 comprises at least a wire clip 10 and at least a fastener 30 engaging with the wire clip 10. In the illustrated embodiment, there is a pair of wire clips 10 correspondingly engaging with a pair of fasteners 30, and also with the heat sink 20.

Each wire clip 10 is integrally made of a single monolithic piece of resilient metal wire. The wire clip 10 comprises two opposite engaging arms 14, and an engaging section 13 interconnecting the two engaging arms 14. Each engaging arm 14 comprises a connecting section 11 extending perpendicularly from the engaging section 13, and a hook 12 bent outwardly from a free end of the connecting section 11. The engaging section 13 is curved and defines a through opening 130. In the illustrated embodiment, the engaging section 13 is U-shaped and defines the through opening 130 in the hollow of the U-shape. The connecting section 11 comprises a first portion 111 extending outwardly from the engaging section 13, and a second portion 112 bent from the first portion 111. The first portion 111 of the connecting section 11 of each engaging arm 14 is coplanar with the engaging section 13. The hook 12 of each engaging arm 16 is perpendicularly bent from a free end of the second portion 112 of the connecting section 11, and the hook 12 is coplanar with the second portion 112. The first portion 111 is inclined upwardly relative to the second portion 112 of the connecting section 11 of each engaging arm 14. The two hooks 12 of the two engaging arms 14 of each wire clip 10 extend away from each other in substantially opposite directions.

The heat sink 20 is integrally made of a material having a good heat conductivity coefficient, such as copper, aluminum, or an alloy thereof. The heat sink 20 comprises a base plate 22 and a plurality of fins 25 protruded upwardly from a top face of the base plate 21. The base plate 22 is a rectangular plate with a uniform thickness. A center of a bottom of the base plate 22 is thermally attached on the electronic component 40. Each fin 25 is an elongated strip and perpendicular to the top face of the base plate 22. The fins 25 are spaced from and parallel to each other. The base plate 22 transfers heat to the fins 25, and the fins 25 dissipate the heat by natural air convection and thermal radiation.

The plurality of fins 25 define a receiving groove 23 at a center thereof, and two parallel receiving slots 24 at two sides thereof, for accommodating the wire clips 10 of the clip assembly 100. The receiving groove 23 can be considered to extend in a transverse direction through the plurality of fins 25. Each receiving slot 24 can be considered to extend lengthways through the plurality of fins 25. That is, the direction that each receiving groove 23 extends along is perpendicular to the direction that the receiving slot 24 extends along. A central part of a top face of the base plate 22 is exposed by the receiving groove 23. The second portions 112 of the connecting sections 11 of each wire clip 10 are located in the receiving groove 23, and abut against the top face of the base plate 22. The two hooks 12 of each wire clip 10 are respectively inserted into and hooked in a corresponding one of the receiving slots 24. In the present embodiment, the engaging sections 13 of the two wire clips 10 are located at two opposite lateral (long) sides of the heat sink 20.

Each of the fasteners 30 comprises a cap-shaped head 31, a cylindrical post 32 extending coaxially downwardly from a bottom of the head 31, and an annular protrusion (ring) 33 protruding outwardly from an outer circumference of the post 32. A crisscross groove 310 is defined in a top face of the head 31, and is adapted for facilitating a tool to operate the fastener 30. An outer periphery of a bottom end of the post 32 is threaded for screwing into the printed circuit board 50. A diameter of the post 32 is smaller than that of the head 31. The protrusion 33 is spaced from the head 31 and located at about a middle of the post 32.

In assembly of the heat dissipation device, each fastener 30 extends through the through opening 130 of the engaging section 13 of the corresponding wire clip 10, the post 32 of the fastener 30 is encircled by the engaging section 13, and the engaging section 13 is sandwiched between the head 31 and the annular protrusion 33 of the fastener 30. A downward pressure is exerted on the fastener 30 by, e.g., a human operator, to make the post 32 extend towards the printed circuit board 50, and then the post 32 is screwed into the printed circuit board 50. The engaging section 13 is pressed downwardly by the head 31 of the fastener 30, and correspondingly the first portions 111 of the connecting sections 11 are resiliently deformed downwardly. The hooks 12 of the wire clip 10 are snugly hooked in the corresponding receiving slot 24. A resilient deformation of the wire clip 10 causes the second portions 112 of the wire clip 10 to press the base plate 22 of the heat sink 20 downwardly. Thereby, the heat sink 20 and the printed circuit board 50 are finally secured together by the clip assembly 100, and the base plate 22 is tightly attached on the electronic component 40.

Additionally, the engaging portion 13 of each wire clip 10 is resiliently pressed by the head 31 of the corresponding fastener 30. The more the head 31 of the fastener 30 presses downwardly on the engaging section 13, the more the wire clip 10 resiliently deforms, and the greater the amount of the force exerted on the heat sink 20. Thus, an appropriate force exerted by the clip assembly 100 on the heat sink 20 can be easily obtained by controlling the depth that the fasteners 30 are screwed into the printed circuit board 50.

It is to be further understood that even though numerous characteristics and advantages of the present embodiments have been set forth in the foregoing description, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A heat dissipation device for dissipating heat generated by an electronic component mounted on a printed circuit board, the heat dissipation device comprising:
a heat sink; and
a clip assembly pressing the heat sink towards the electronic component, the clip assembly comprising two wire clips and two fasteners engaging with the wire clips, respectively, each wire clip comprising two opposite engaging arms, and an engaging section interconnecting the two engaging arms, each engaging arm comprising a connecting section extending outwardly from the engaging section, and a hook bent outwardly from a free end of the connecting section;
wherein the hooks of each wire clip are hooked in the heat sink, each fastener extends through the engaging section of the corresponding wire clip and is screwed into the printed circuit board, the engaging section of the wire clip is resiliently pressed by the fastener, and the heat sink is pressed downwardly by the connecting section of the wire clip.

2. The heat dissipation device of claim 1, wherein the heat sink comprises a base plate and a plurality of fins protruding upwardly from the base plate.

3. The heat dissipation device of claim 2, wherein the fins define a receiving slot for accommodating the hooks of the wire clip.

4. The heat dissipation device of claim 3, wherein the connecting sections of each wire clip abut against a top face of the base plate, and the fins define a receiving groove for accommodating the second portions of the connecting sections of the wire clip.

5. The heat dissipation device of claim 3, wherein the receiving slot extends in a transverse direction through the fins.

6. The heat dissipation device of claim 1, wherein the two engaging sections of the two wire clips are located at two opposite lateral sides of the heat sink.

7. The heat dissipation device of claim 1, wherein the engaging section of each wire clip is curved and defines a through opening for the corresponding fastener to extend through.

8. The heat dissipation device of claim 1, wherein the connecting section of each engaging arm comprises a first portion extending outwardly from the engaging section, and a second portion bent from the first portion, and the first portion is inclined upwardly relative to the second portion.

9. The heat dissipation device of claim 8, wherein the first portion of the connecting section of each engaging arm is coplanar with the engaging section.

10. The heat dissipation device of claim 8, wherein the hook of each engaging arm is bent from a free end of the second portion of the connecting section of each wire clip, and the hook is coplanar with the second portion.

11. A clip assembly comprising:
a wire clip comprising two opposite engaging arms, and an engaging section interconnecting the two engaging arms, each engaging arm comprising a connecting section extending outwardly from the engaging section, and a hook bent outwardly from a free end of the connecting section, and the connecting section of each engaging arm comprising a first portion extending outwardly from the engaging section, and a second portion extending from the first portion; and
a fastener for engaging with the engaging section of the wire clip, wherein the first portion bends up from the second portion such that when the fastener presses down on the engaging section and the second portion remains in a fixed position at least the first portion resiliently deforms.

12. The clip assembly of claim 11, wherein the engaging section of the wire clip is curved and defines a through opening for the fastener to extend through.

13. The clip assembly of claim 11, wherein the first portion is inclined upwardly relative to the second portion of the connecting section.

14. The clip assembly of claim 11, wherein the first portion of the connecting section of each engaging arm is coplanar with the engaging section.

15. The clip assembly of claim 11, wherein the hook of each engaging arm is bent from a free end of the second portion of the connecting section, and the hook is coplanar with the second portion.

16. The clip assembly of claim 11, wherein the two hooks extend away from each other in substantially opposite directions.

17. The clip assembly of claim 11, wherein the wire clip is integrally made of a resilient metal wire.
